(19) United States
(12) Patent Application Publication
(10) Pub. No.: US 2026/0239796 A1
(43) Pub. Date: Aug. 13, 2026

(54) ELECTRONIC DEVICE

(71) Applicant: InnoLux Corporation, Miao-Li County (TW)

(72) Inventors: Yu-Ting TSAI, Miao-Li County (TW); Wei-Ju LIAO, Miao-Li County (TW); Yu-Tsung LIU, Miao-Li County (TW); I-An YAO, Miao-Li County (TW)

(73) Assignee: InnoLux Corporation, Miao-Li County (TW)

(21) Appl. No.: 19/454,443

(22) Filed: Jan. 21, 2026

(30) Foreign Application Priority Data
Feb. 10, 2025 (CN) 202510142582.5

(51) Int. Cl. H10H 29/80; G09G 3/00

(52) U.S. Cl. CPC H10H 29/8321; G09G 3/006

(57) ABSTRACT

An electronic device is provided and includes a substrate, a plurality of electronic units, a first wire, a bonding pad, a probe pad, and a cover plate. The substrate includes an active region and a peripheral region. The electronic units are disposed in the active region. The first wire is disposed on the substrate and electrically connected to one of the plurality of electronic units. The bonding pad is disposed in the peripheral region and electrically connected to the first wire. The probe pad is disposed in the peripheral region and electrically connected to the first wire. The cover plate is disposed opposite to the substrate, and the cover plate is bonded to the substrate to form a cavity. The electronic units and the probe pad are disposed in the cavity, and the bonding pad is disposed outside the cavity.

### BACKGROUND OF THE DISCLOSURE

### 1. FIELD OF THE DISCLOSURE

The present disclosure relates to an electronic device and particularly to an electronic device including bonding pads and probe pads.

### 2. DESCRIPTION OF THE PRIOR ART

In order to test whether elements formed in the process steps for manufacturing electronic devices or the completed electronic devices are functioning normally, the bonding pads in the electronic devices used for electrical connection with external element will also serve as probe pads. However, during testing, the testing probe needs to contact the bonding pads, which easily causes scratches on the bonding pads, resulting in poor reliability of the bonding pads while being boned to the external element. In addition, the bonding pads used as the probe pads need to be exposed during the manufacturing process steps, so that the process steps performed after the bonding pads are formed easily damage the exposed bonding pads. As a result, how to maintain the quality of the bonding pads and the lifespan of the elements while performing testing in the process steps for manufacturing the electronic device is an issue in this field.

### SUMMARY OF THE DISCLOSURE

An objective of the present disclosure is to provide an electronic device to improve the reliability of the bonding between bonding pads and external element.

An embodiment of the present disclosure provides an electronic device including a substrate, a plurality of electronic units, a first wire, a bonding pad, a probe pad, and a cover plate. The substrate includes an active region and a peripheral region. The electronic units are disposed in the active region. The first wire is disposed on the substrate and electrically connected to one of the plurality of electronic units. The bonding pad is disposed in the peripheral region and electrically connected to the first wire. The probe pad is disposed in the peripheral region and electrically connected to the first wire. The cover plate is disposed opposite to the substrate, and the cover plate is bonded to the substrate to form a cavity. The electronic units and the probe pad are disposed in the cavity, and the bonding pad is disposed outside the cavity.

In the electronic device and its manufacturing method of the present disclosure, since the bonding pads and probe pads are separately disposed, damage to the bonding pads during testing through the probe pads and/or subsequent process steps may be prevented or reduced, thereby improving the reliability of bonding between the bonding pads and external elements.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1A schematically illustrates a top view of an electronic device during an assembling process according to a first embodiment of the present disclosure.

FIG. 1B schematically illustrates a cross-sectional view of the electronic device during an assembling process according to the first embodiment of the present disclosure.

FIG. 1C schematically illustrates a cross-sectional view of the electronic device taken along a line B-B' of FIG. 1A according to some embodiments of the present disclosure.

FIG. 2 schematically illustrates a circuit diagram illustrating an electronic device according to an embodiment of the present disclosure.

FIG. 3 schematically illustrates a top view of an electronic device during an assembling process according to a second embodiment of the present disclosure.

FIG. 4A schematically illustrates a top view of an electronic device during an assembling process according to a variant embodiment of the first embodiment of the present disclosure.

FIG. 4B schematically illustrates a cross-sectional view of the electronic device during the assembling process according to the variant embodiment of the first embodiment of the present disclosure.

FIG. 5 schematically illustrates a top view of an electronic device during an assembling process according to a third embodiment of the present disclosure.

FIG. 6 schematically illustrates an enlarged view of a first multiplexer, probe pads and the bonding pads according to the third embodiment of the present disclosure.

FIG. 7 schematically illustrates a top view of an electronic device during an assembling process according to a fourth embodiment of the present disclosure.

FIG. 8 schematically illustrates a top view of an electronic device during an assembling process according to a fifth embodiment of the present disclosure.

FIG. 9 schematically illustrates an enlarged view of a first multiplexer, the probe pads, a second multiplexer, and the bonding pads according to the fifth embodiment of the present disclosure.

FIG. 10 schematically illustrates a top view of an electronic device during an assembling process according to a sixth embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure are simplified schematic diagrams, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to…”.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may, for example, include a display device, a light emitting device, a package device, or other suitable electronic devices, but not limited thereto. The electronic device may be a flexible electronic device, but not limited thereto. The display device may, for example, be applied to a laptop, a public display, a tiled display, a car display, a touch display, a TV, a monitor, a smartphone, a tablet, a light source module, but not limited thereto.

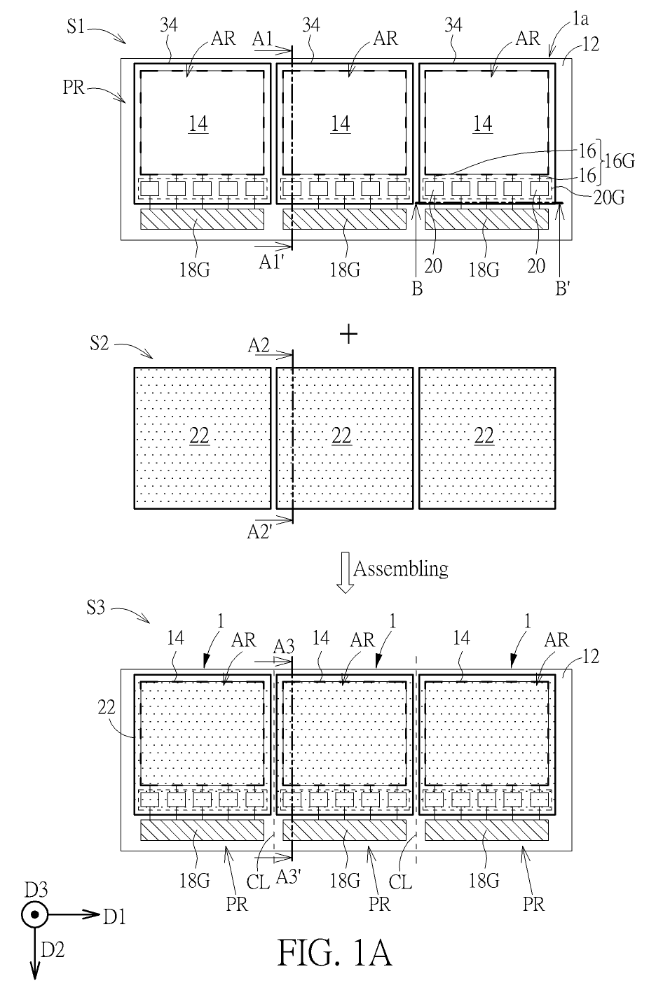

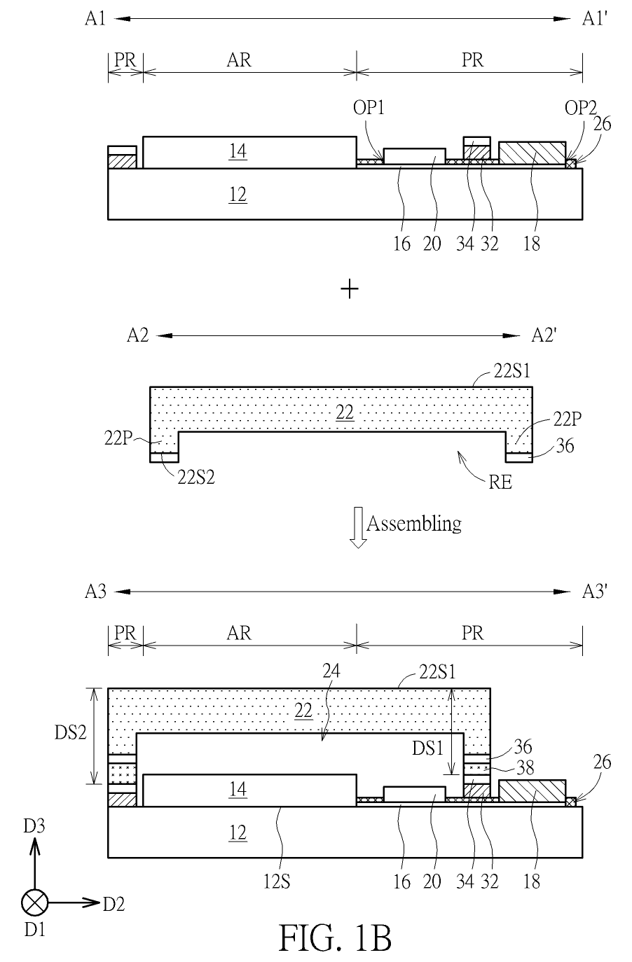

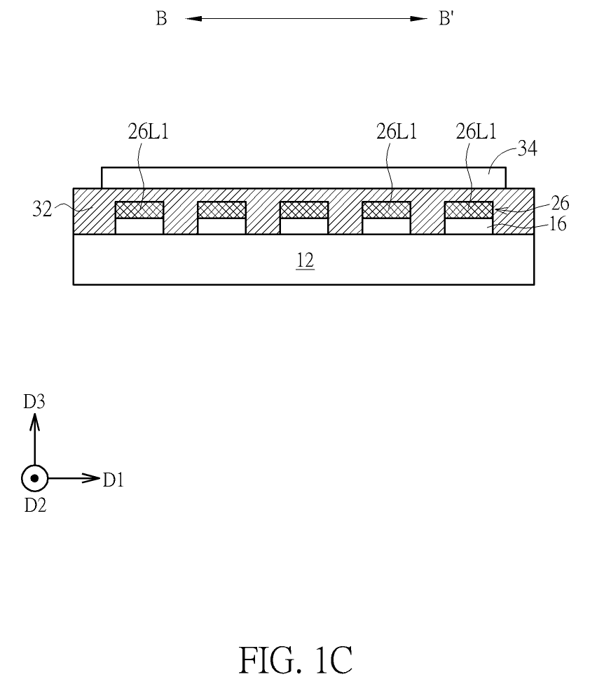

In the following drawings, a direction D1, a direction D2, and a direction D3 are indicated. The direction D3 may represent a normal direction or a top-view direction of the electronic device. As shown in FIG. 1B, the direction D3 may be perpendicular to an upper surface 12S of a substrate 12. The direction D1 and the direction D2 may be horizontal directions and may be perpendicular to the direction D3. As shown in FIG. 1B, the direction D1 and the direction D3 may be parallel to the upper surface 12S of the substrate 12. The spatial relationships of the structures in the following drawings may be described based on the direction D1, the direction D2, and the direction D3.

Refer to FIG. 1A and FIG. 1B. FIG. 1A schematically illustrates a top view of an electronic device during an assembling process according to a first embodiment of the present disclosure, and FIG. 1B schematically illustrates a cross-sectional view of the electronic device during the assembling process according to the first embodiment of the present disclosure, wherein an upper part, a middle part, and a lower part of FIG. 1B are schematic cross-sectional views along a line A1-A1’, a line A2-A2’, and a line A3-A3’ of FIG. 1A, respectively. As shown in FIGS. 1A and 1B, a method for manufacturing an electronic device 1 provided in this embodiment may include performing step S1, step S2, and step S3. Specifically, in step S1, a semi-finished structure 1a may be formed, wherein the semi-finished structure 1a may include a substrate 12, a plurality of electronic elements 14, a plurality of wire groups 16G, a plurality of bonding pad groups 18G, a plurality of probe pad groups 20G, and a plurality of first bonding elements 34. For example, the electronic elements 14 may be arranged along the direction D1. The wire groups 16G may be arranged along the direction D1. The bonding pad groups 18G may be arranged along the direction D1, and the probe pad groups 20G may be arranged along the direction D1, but not limited thereto. The first bonding elements 34 may surround the corresponding electronic elements 14 and the corresponding probe pad groups 20G, respectively. In this embodiment, the first bonding elements 34 may overlap the corresponding wire groups 16G, respectively, but not limited thereto. In some embodiments, the arrangement of the electronic elements 14, the wire groups 16G, the bonding pad groups 18G, and the probe pad groups 20G may be adjusted according to requirements.

In step S2, a plurality of cover plates 22 may be formed, wherein each cover plate 22 is provided with a second bonding element 36. In this embodiment, each cover plate 22 may have an upper surface 22S1 and a lower surface 22S2 opposite to each other, and the lower surface 22S2 may have a recess RE. Specifically, the cover plate 22 may have a protrusion 22P surrounding the recess RE, and the second bonding element 36 may be disposed on the lower surface 22S2 of the protrusion 22P of the corresponding cover plate 22. Since step S1 and step S2 do not affect each other, step S1 may be performed before, after or during performing step S2.

After step S1 and step S2, step S3, i.e., the assembling process, may be performed to assemble the cover plates 22 with the substrate 22 of the semi-finished structure 1a to form a plurality of electronic devices 1. In step S3, a plurality of sealing elements 38 may be first disposed on the first bonding elements 34, respectively. Then, the second bonding elements 36 may be disposed on the sealing elements 38 with the second bonding elements 36 aligned with the first bonding elements 34 in the direction D3, respectively. A melting process is then performed to bond the cover plates 22 to the substrate 22, thereby securing the cover plates 22 to the substrate 12 to form cavities 24. In other words, the cover plates 22 may be disposed on the substrate 12 and bonded to the substrate 12 with the recess RE facing the substrate 12, thereby forming the cavities 24. Subsequently, a cutting process may be performed along cutting lines CL to separate the electronic devices 1 from one another. The direction D3 may be, for example, the normal direction perpendicular to the upper surface 12S of the substrate 12.

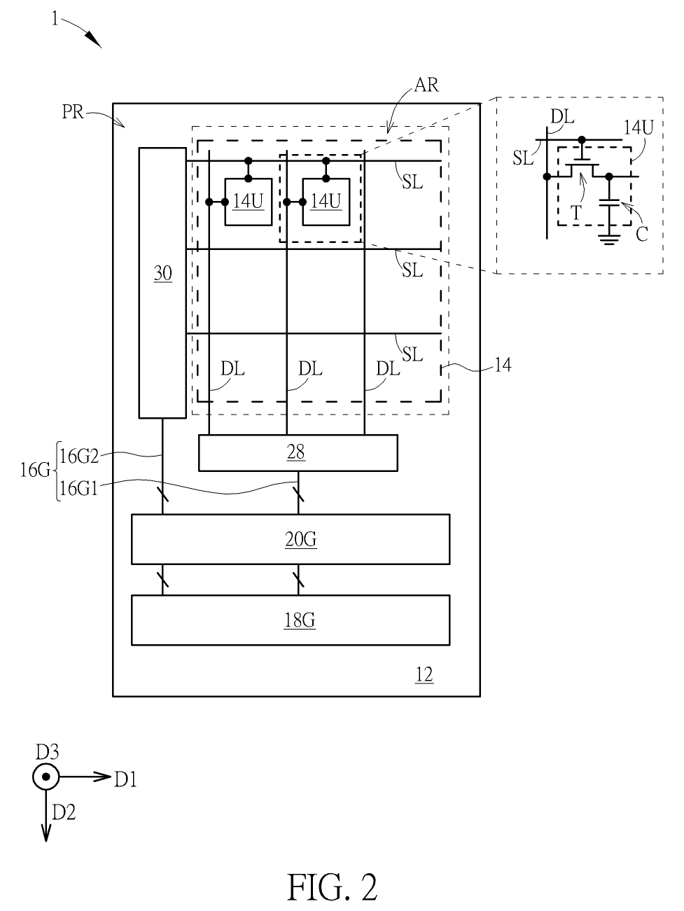

In order to clarify the electronic device 1 of this embodiment, a single electronic device 1 is described below, but the present disclosure is not limited thereto. As shown in FIGS. 1A and 1B, the electronic device 1 provided in this embodiment includes the substrate 12, a plurality of electronic units (e.g., electronic units 14U shown in FIG. 2), a first wire, a bonding pad 18, a probe pad 20, and a cover plate 22. The substrate 12 may include an active region AR and a peripheral region PR, wherein the electronic units are disposed in the active region AR, and the bonding pad 18 and the probe pad 20 are disposed in the peripheral region PR. The first wire is disposed on the substrate 12 and electrically connected to at least one of the electronic units, and the bonding pad 18 and the probe pad 20 are electrically connected to the first wire. The cover plate 22 is disposed opposite to the substrate 12, and the cover plate 22 is bonded to the substrate 12 to form the cavity 24, wherein the electronic units and the probe pad 20 are located in the cavity 24, and the probe pad 20 is located outside the cavity 24. It is worth noting that since the bonding pad 18 and the probe pad 20 are disposed separately from each other, damage to the bonding pad 18 during testing through the probe pad 20 may be avoided, thereby improving the reliability of the bonding between the bonding pad 18 and external elements. In this embodiment, the first wire may be, for example, a wire 16 shown in FIG. 1A or a wire DL or a wire SL shown in FIG. 2.

Specifically, the active region AR may be a region of the substrate 12 for disposing the electronic units. As shown in FIGS. 1A and 1B, the electronic device 1 may include an electronic element 14 disposed in the active region AR, and the electronic element 14 may include a plurality of electronic units. Although FIGS. 1A and 1B do not show the electronic units, the position of the electronic units may be represented by the position of the electronic element 14, and the electronic units may be located in the active region AR. For ease of explanation, the electronic units of this embodiment take electronic units 14U in FIG. 2 as an example, but not limited thereto. The electronic element 14 may, for example, have a signal transmission, sensing, or other suitable function. In other words, the active region AR for disposing the electronic element 14 may, for example, be a region having a sensing function or a signal transmission function. The signal transmission function may, for example, include displaying an image, emitting light, or other suitable function. The electronic unit may, for example, be a pixel or sub-pixel for emitting light or detecting light. The peripheral region PR may be a region of the substrate 12 located outside the active region AR, and may, for example, be a region for disposing peripheral circuits.

The substrate 12 may include, for example, quartz, glass, wafer, sapphire, resin, epoxy resin, polycarbonate (PC), polyimide (PI), polypropylene (PP), other plastic materials, or a combination thereof.

In this embodiment, the electronic device 1 may include the wire group 16G and the probe pad group 20G, wherein the wire group 16G may include a plurality of wires 16, and the probe pad group 20G may include a plurality of probe pads 20. Each probe pad 20 may be electrically connected to a corresponding wire 16, i.e., the number of the probe pads 20 may be equal to the number of the wires 16. The wires 16 may include metal for transmitting sensing signals, driving signals or driving voltages. The metal may include, for example, aluminum or other suitable materials. The probe pads 20 may, for example, include metal or other suitable materials. In FIGS. 1A and 1B, the wires 16 may be disposed on the substrate 12 in the peripheral region PR and used for electrically connecting the corresponding probe pads 20 to the corresponding electronic units in the active region AR. In the embodiment of FIG. 1B, the probe pads 20 and the wires 16 may be formed by different process steps, and the probe pads 20 may respectively overlap the corresponding wires 16 in the direction D3, but not limited thereto. In some embodiments, the wires 16 and the probe pads 20 may be formed by the same process step. In some embodiments, the wires 16 and the probe pads 20 may include the same or different materials. In the embodiment of FIG. 1A, a width of the probe pad 20 in the direction D1 may be greater than a width of the wire 16 in the direction D1, but not limited thereto.

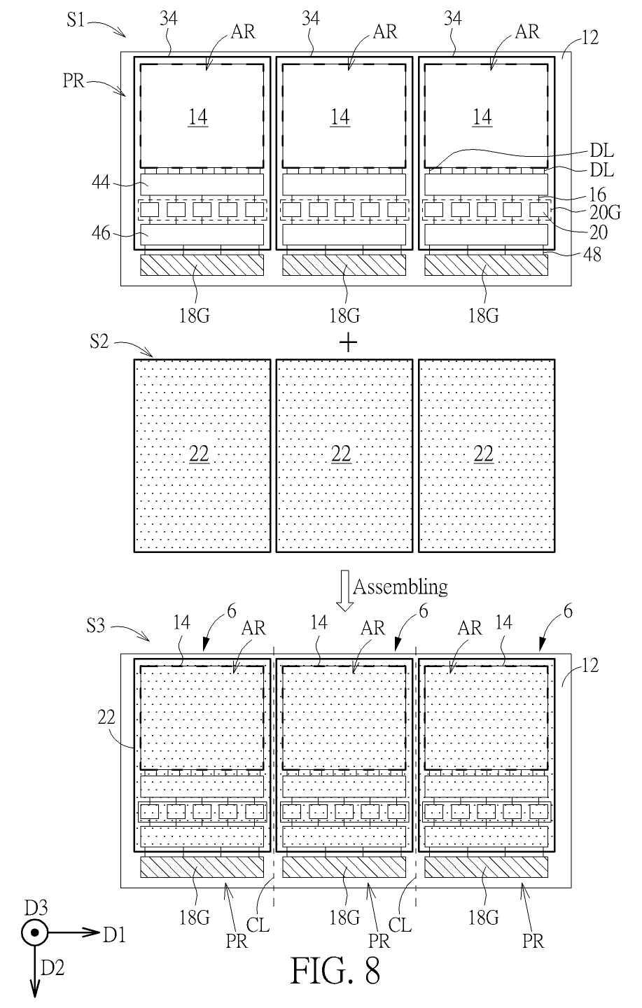

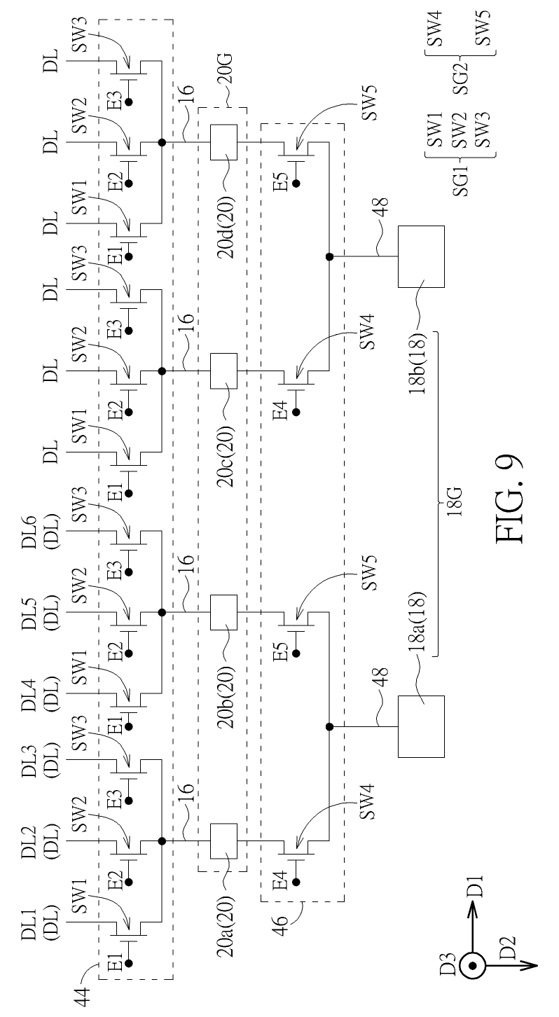

The bonding pad group 18G in FIG. 1A may include a plurality of bonding pads 18 as shown in FIG. 1B, and the bonding pads 18 may be separated from each other. As shown in FIGS. 1A and 1B, the bonding pads 18 may be used for being bonded to external circuit structure, such as chip (IC), flexible printed circuit (FPC), or other suitable elements. It should be noted that, since the probe pads 20 are not used as the bonding pads 18, the bonding pads 18 and the probe pads 20 may be formed by different process steps. The bonding pads 18 may be formed after process steps that are likely to damage exposed bonding pads 18, for example after the probe pads 20 are formed. Alternatively, the bonding pads 18 and the probe pads 20 may be formed in the same process step, and an insulating layer used for protecting the bonding pads 18 may be formed on the bonding pads 18 before performing any process step that may damage the exposed bonding pads 18. This insulating layer may be removed before the semi-finished structure 1a is completed, thereby reducing or preventing damage to the bonding pads 18. In this embodiment, the bonding pads 18 and the probe pads 20 may be located on the same side of the active region AR. Each bonding pad 18 may be disposed on the corresponding wire 16, such that the bonding pads 18 may be electrically connected to the corresponding probe pads 20 in a one-to-one correspondence, and the number of the bonding pads 18 may be equal to the number of the probe pads 20, but not limited thereto. In some embodiments, the number of the bonding pads 18 may differ from the number of the probe pads 20, and for example, the number of the bonding pads 18 is less than that of the probe pads 20. That is, one of the bonding pads 18 may be electrically connected to multiple probe pads 20, as shown in FIGS. 8 and 9, but not limited thereto. In some embodiments, the bonding pads 18 may be electrically connected to the probe pads 20 through other wires, but not limited thereto. The bonding pads 18 and the probe pads 20 may be used for providing signals to the electronic units or for reading signals from the electronic units based on requirements.

As shown in FIGS. 1A and 1B , the electronic device 1 may further include a protective layer 26 disposed on the wires 16 to protect the wires 16 and reduce damage, such as oxidation or physical impact, to the wires 16. In this embodiment, the protective layer 26 may include an insulating material. In this case, a top-view outline of the protective layer 26 may differ from that of the wires 16. For example, the protective layer 26 may be simultaneously disposed on different wires 16 and may include a plurality of openings OP1 and a plurality of openings OP2, allowing the probe pads 20 and the bonding pads 18 to be electrically connected to the corresponding wires 16 through the openings OP1 and the openings OP2, respectively. In the embodiment of FIG. 1B, the probe pads 20 and the bonding pads 18 may each contact the corresponding wires 16, but not limited thereto. The protective layer 26 may extend to two side surfaces of each wire 16 and/or an end surface of each wire 16 near an edge of the substrate 12, thereby reducing the ingress of moisture into the active region AR from the exposed wires 16. Thus, the impact of moisture on the lifespan of the electronic units may be avoided or mitigated.

FIG. 1C schematically illustrates a cross-sectional view of the electronic device taken along a line B-B' of FIG. 1A according to some embodiments of the present disclosure. As shown in FIG. 1C, in some embodiments, the protective layer 26 may include a conductive material, such as metal. In this case, the top-view outline of the protective layer 26 may be the same as that of the wires 16. For example, the protective layer 26 may include a plurality of protective wires 26L1, separated from each other and respectively corresponding to the wires 16. In other words, the number of the protective wires 26L1 may be the same as the number of the wires 16, but not limited thereto. In this case, the protective wires 26L1 may be disposed on the wires 16, respectively, and located between the probe pads 20 and the wires 16 and between the bonding pads 18 and the wires 16. In some embodiments, the wire 16 may include aluminum, and the protective layer 26 may include molybdenum, such that the wire 16 and the corresponding protective wire 26L1 may form a metal stack.

In the embodiment shown in FIGS. 1A and 1B, the electronic device 1 may further include a buffer layer 32, a first bonding element 34, a second bonding element 36, and a sealing element 38, wherein the buffer layer 32, the first bonding element 34, the second bonding element 36, and the sealing element 38 may, for example, have an annular shape in the direction D3, surrounding the active region AR/electronic element 14. The buffer layer 32 may be disposed on the wires 16 and cross the wires 16, and the first bonding element 34 is disposed on the buffer layer 32. Furthermore, the second bonding element 36 is disposed on the protrusion 22P of the cover plate 22, and the sealing element 38 is disposed between the first bonding element 34 and the second bonding element 36. In some embodiments, as shown in the cross-sectional view of FIG. 1C, the buffer layer 32 may be located between the plurality of wires 16 and the first bonding element 34. When both the first bonding element 34 and the protective layer 26 include conductive material, the buffer layer 32 may be used for electrically insulating the protective wires 26L1 from the first bonding element 34.

As shown in FIGS. 1A and 1B , the sealing element 38 may be used for bonding the first bonding element 34 to the second bonding element 36.

In one embodiment, the cavity 24 may be in a vacuum state, wherein the term "vacuum" refers to a condition in which a pressure in the cavity 24 is, for example, less than or equal to 1 torr. For instance, the pressure in the cavity 24 may range from 10⁻³ torr to 1 torr, or from 10⁻⁷ torr to 1 torr, but the present disclosure is not limited thereto.

The cover plate 22 may allow light of a specific wavelength, such as ranging from 5 micrometers (μm) to 15 μm, to pass through, but not limited thereto. It should be noted that, since a portion of the first bonding element 34 overlaps the first wire 16, and another portion of the first bonding element 34 does not overlap the first wire 16, a distance DS1 between an upper surface 22S1 of the cover plate 22 and the portion of the first bonding element 34 that overlaps the first wire 16 is different from a distance DS2 between the upper surface 22S1 and the another portion of the first bonding element 34 that does not overlap the first wire 16. In other words, when bonding the first bonding element 34 to the second bonding element 36, a height of a gap between the first bonding element 34 and the second bonding element 36 may vary at different positions. For example, a portion of the gap that overlaps the first wire 16 may be less than another portion of the gap that does not overlap the first wire 16. The gap may refer to a distance between the upper surface of the first bonding element 34 and the lower surface of the second bonding element 36. In this embodiment, the sealing element 38 may be configured to fill up the gap with varying heights by calculating its wetting volume.

Refer to FIG. 2, which schematically illustrates a circuit diagram illustrating an electronic device according to an embodiment of the present disclosure. As shown in FIG. 2, the electronic element 14 may include a plurality of electronic units 14U, arranged in an array or in other suitable arrangements. The electronic device 1 may further include a plurality of wires DL and a plurality of wires SL, disposed in the active region AR. The wires DL may extend along the direction D2 and be arranged along the direction D1, while the wires SL may extend along the direction D1 and be arranged along the direction D2. The direction D1 is different from the direction D2, and for example, the direction D1 may be perpendicular to the direction D2. Each electronic unit 14U may be disposed in the active region AR and electrically connected to a corresponding wire DL and a corresponding wire SL. For example, the electronic units 14U arranged in the same column or along the direction D2 may be electrically connected to the same wire DL, and electronic units 14U arranged in the same row or along the direction D1 may be electrically connected to the same wire SL. In other words, the electronic device 1 may further include a second wire disposed on the substrate 12 and electrically connected to at least another one of the electronic units 14U. The second wire may refer to a wire different from the first wire but included in the same wire group as the first wire.

In the embodiment of FIG. 2, the electronic unit 14U may include a transistor T and a capacitor C, wherein a gate and a source of the transistor T are respectively electrically connected to the corresponding wire SL and the corresponding wire DL, and two terminals of the capacitor C are respectively electrically connected to a drain of the transistor T and a ground terminal, but not limited thereto. For example, the electronic unit may include a capacitor, a resistor, an inductor, a varactor diode, a variable capacitor, a diode, a transistor transducer, a MEMS element, a sensor, etc., but not limited thereto.

The electronic device 1 may further include a column driver 28 and a row driver 30, both disposed in the peripheral region PR of the substrate 12. The column driver 28 may be electrically connected to the wires DL, and the row driver 30 may be electrically connected to the wires SL. As shown in FIG. 2, the wire groups 16G may, for example, include a wire group 16G1 and a wire group 16G2, wherein the wire group 16G1 may electrically connect part of the probe pads of the probe pad group 20G to the column driver 28, so as to be electrically connected to the wires DL, while the wire group 16G2 may electrically connect another part of the probe pads of the probe pad group 20G to the row driver 30, so as to be electrically connected to the wires SL. The wire group 16G1 and the wire group 16G2 may each include one or more wires 16 as shown in FIG. 1A. For example, the probe pads of the probe pad group 20G may be electrically connected to the wires DL and wires SL in a one-to-one correspondence, but not limited thereto. Moreover, the bonding pads of the bonding pad group 18G (e.g., the bonding pad 18 as shown in FIG. 1B) may each be electrically connected to the corresponding probe pad of the probe pad group 20G (e.g., the probe pad 20 as shown in FIGS. 1A and 1B through the wire group 16G.

For simplicity, identical elements in different embodiments will be denoted by the same reference numerals in the present disclosure. To clearly illustrate different embodiments, differences between them will be described, and repeated parts will not be redundantly described.

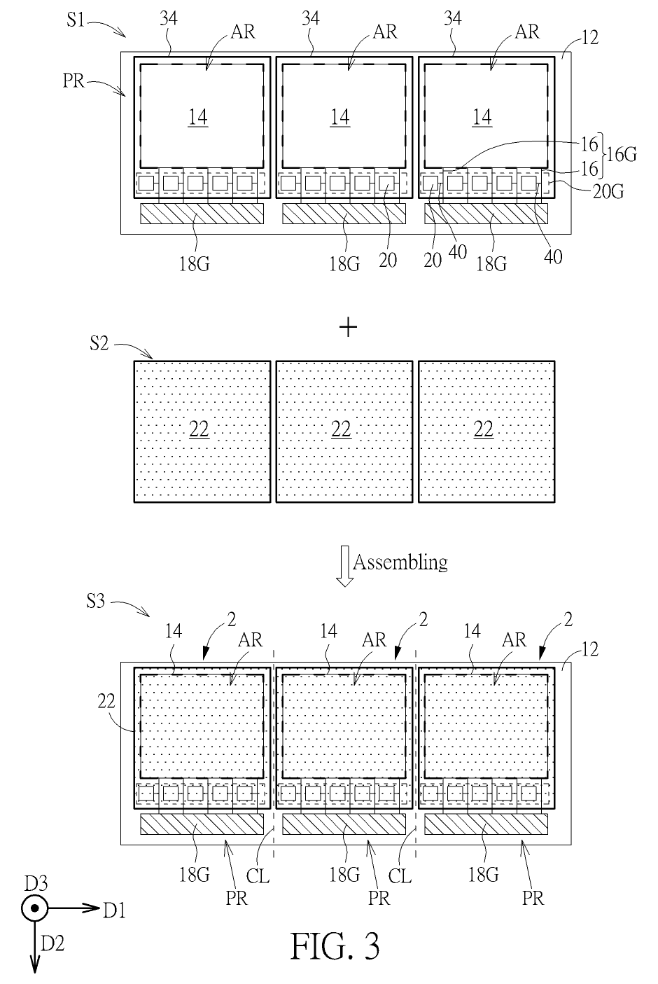

Refer to FIG. 3, which schematically illustrates a top view of an electronic device during an assembling process according to a second embodiment of the present disclosure. As shown in FIG. 3, a difference between the electronic device 2 of this embodiment and the electronic device 1 of FIG. 1A in that the electronic device 2 may further include a branch wire 40, electrically connected between the wire 16 and the probe pad 20. Specifically, the electronic device 2 may include a plurality of branch wires 40, each disposed between a corresponding wire 16 and a corresponding probe pad 20, such that each probe pad 20 may be electrically connected to the corresponding wire 16 through the corresponding branch wire 40 and further be electrically connected to the corresponding electronic unit (e.g., the electronic unit 14U shown in FIG. 2) and corresponding bonding pad 18. In some embodiments, the protective layer 26 as shown in FIGS. 1B or 1C may be provided on the branch wire 40. For example, the protective layer 26 in FIG. 1B may be simultaneously disposed on a plurality of branch wires 40, or the protective layer 26 in FIG. 1C may include a plurality of protective wires respectively disposed on the branch wires 40. Other parts and the manufacturing method of the electronic device 2 in this embodiment may be similar or identical to those of the electronic device 1 and its manufacturing method mentioned above, and therefore reference may be made to the above-mentioned description and will not be repeated here. In some embodiments, the branch wires 40 of this embodiment may be applied to the electronic device of any of the following embodiments.

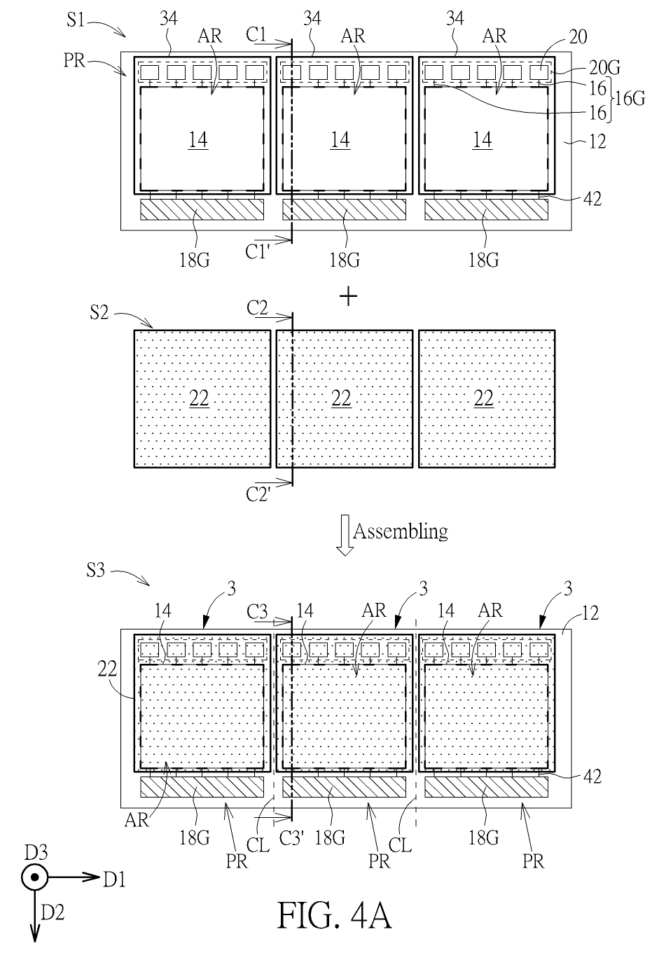

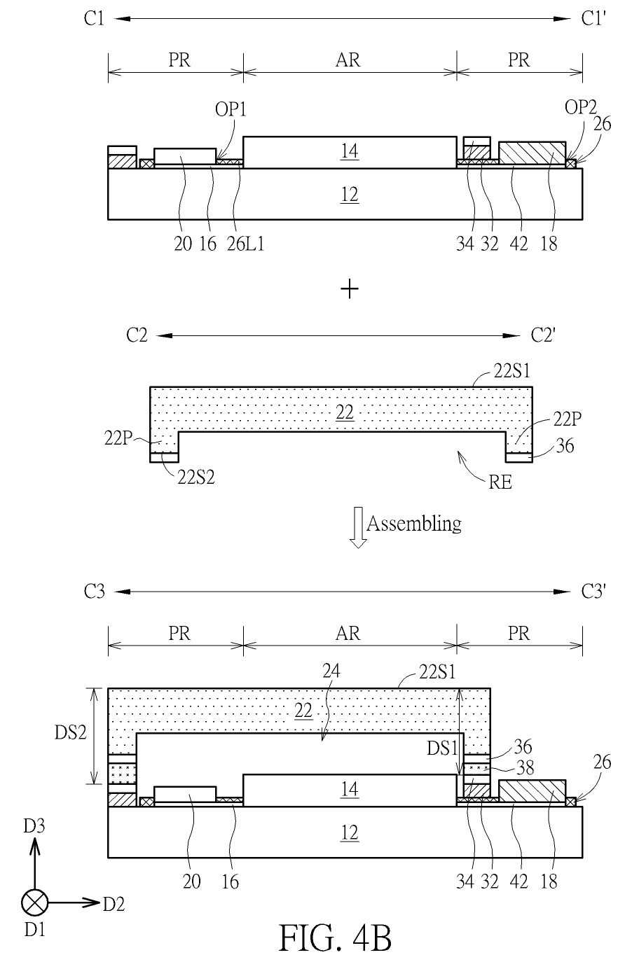

Refer to FIGS. 4A and 4B. FIG. 4A schematically illustrates a top view of an electronic device during an assembling process according to a variant embodiment of the first embodiment of the present disclosure, and FIG. 4B schematically illustrates a cross-sectional view of the electronic device during the assembling process according to the variant embodiment of the first embodiment of the present disclosure. As shown in FIGS. 4A and 4B, a difference between electronic device 3 provided in this variant embodiment and electronic device 1 of FIGS. 1A and 1B is that the probe pads 20 and the bonding pads 18 are located on two opposite sides of the active region AR. Specifically, the probe pads 20 and wires 16 may be located in the cavity (e.g., the cavity 24 shown in FIG. 1B). The electronic device 3 may further include a plurality of wires 42 disposed between the active region AR and the bonding pad group 18G, and the wires 42 may electrically connect the bonding pads 18 of the bonding pad group 18G to the corresponding electronic units (e.g., the electronic units 14U shown in FIG. 2). In this variant embodiment, the bonding pads of the bonding pad group 18G (e.g., the bonding pad 18 shown in FIG. 1B) may each be electrically connected to the corresponding wire 16 through the wire 42 and the electronic element 14, and further be electrically connected to the corresponding probe pad 20, but not limited thereto. In this embodiment, the first wire may refer to a wire 16 or wire 42 as shown in FIG. 4A, or a wire DL or wire SL as shown in FIG. 2.

As shown in FIG. 4B, the protective layer 26 may be simultaneously disposed on the wires 16 and wires 42. In some embodiments, the protective layer 26 may extend to both side surfaces of the wire 42 and/or the end surface of the wire 42 near the edge of the substrate 12, such that ingress of moisture into the active region AR from the exposed wires 42 may be reduced to prevent or mitigate the impact of moisture on the lifespan of the electronic units. In some embodiments, the protective layer 26 may further include a plurality of protective wires respectively disposed on the corresponding wires 42. Other parts and the manufacturing method of the electronic device 3 in this variant embodiment may be similar or identical to those of the electronic device 1 and its manufacturing method mentioned above, and therefore reference may be made to the above-mentioned description and will not be repeated here.

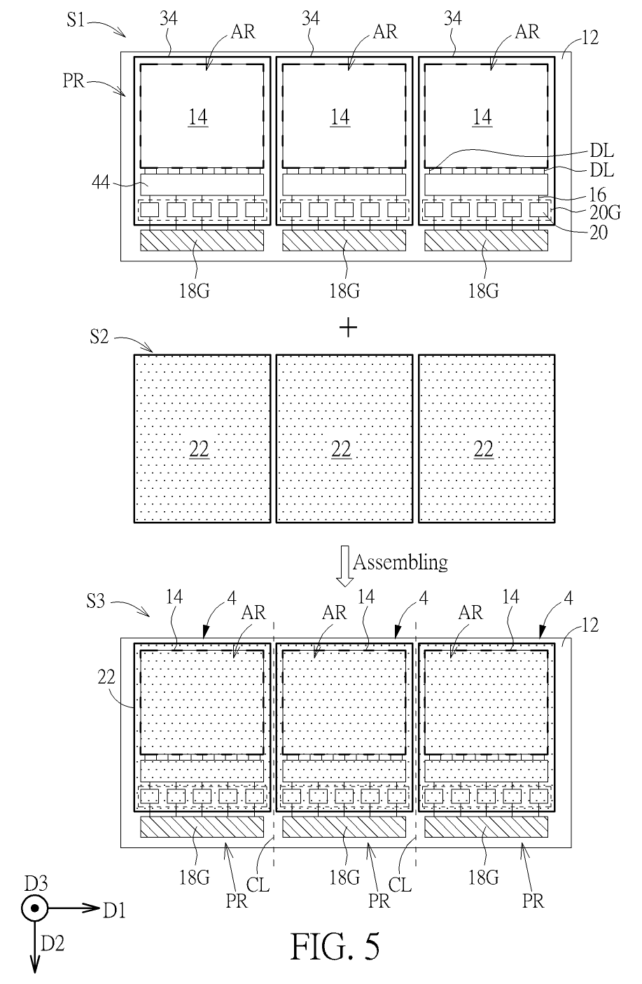

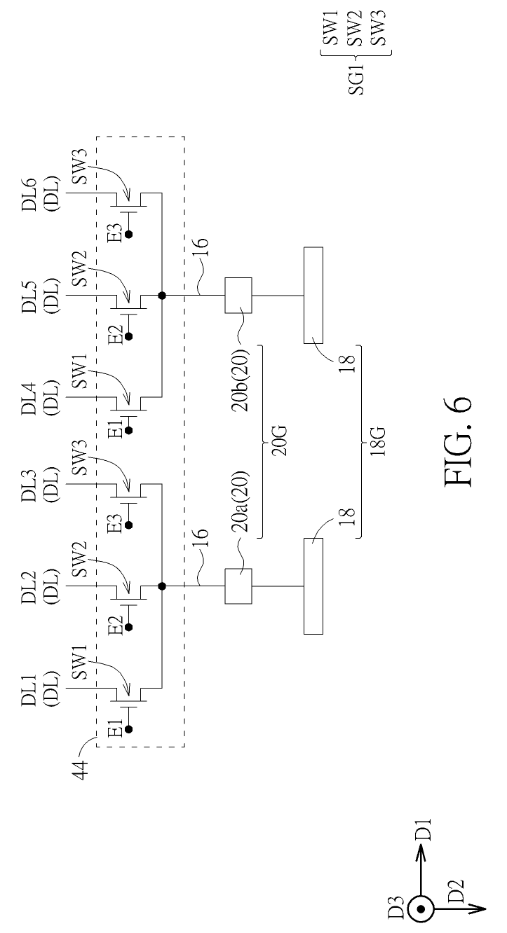

Refer to FIGS. 5 and 6. FIG. 5 schematically illustrates a top view of an electronic device during an assembling process according to a third embodiment of the present disclosure, and FIG. 6 schematically illustrates an enlarged view of a first multiplexer, probe pads and the bonding pads according to the third embodiment of the present disclosure. As shown in FIGS. 5 and 6, a difference between the electronic device 4 provided in this embodiment and the electronic device 1 of FIG. 1A is that the electronic device 4 further includes a first multiplexer 44 disposed on substrate 12 and located in the cavity (e.g., the cavity 24 shown in FIG. 1B), wherein one of the probe pads 20 may be electrically connected to both the first wire and second wire through the first multiplexer 44, such that a single probe pad 20 may be used for testing different electronic units (e.g., the electronic units 14U shown in FIG. 2) electrically connected to different wires through the first multiplexer 44. In this embodiment, the first wire and second wire may be two wires DL, respectively.

Specifically, the first multiplexer 44 may include a plurality of first switching element groups SG1 for switching the electrical connection path between the probe pads 20 and the wires DL. For example, each first switching element group SG1 may include a first switching element SW1, a first switching element SW2, and a first switching element SW3, wherein the first ends of the first switching element SW1, the first switching element SW2, and the first switching element SW3 in one of the first switching element groups SG1 may be electrically connected to each other and to the same probe pad 20, for example, through the corresponding wire 16. The second ends of the first switching element SW1, the first switching element SW2, and the first switching element SW3 in the first switching element group SG1 may be electrically connected to different wires DL. For example, the probe pad 20a may be electrically connected to the wire DL1, the wire DL2, and the wire DL3 through the corresponding first switching element group SG1, and the probe pad 20b may be electrically connected to the wire DL4, the wire DL5, and the wire DL6 through the corresponding first switching element group SG1. Additionally, the control ends of the first switching elements SW1 may be electrically connected to the same control signal terminal E1, the control ends of the first switching elements SW2 may be electrically connected to the same control signal terminal E2, and the control ends of the first switching elements SW3 may be electrically connected to the same control signal terminal E3. By adjusting switching signals provided to the control signal terminal E1, the control signal terminal E2, and the control signal terminal E3, the first switching elements SW1, the first switching elements SW2, and the first switching elements SW3 may be turned on at different times, so that each probe pad 20 is able to be electrically connected to different wires DL at different times, thereby enabling to test different electronic units. In other words, the number of the probe pads 20 in this embodiment may be less than the number of the wires DL, which may help reduce the number of the probe pads 20 or increase areas of the probe pads 20. The first switching element (e.g., the first switching element SW1, the first switching element SW2, and the first switching element SW3) may include a transistor or other suitable switching elements. The first multiplexer 44 may, for example, be formed during the step of forming electronic element 14. In some embodiments, the number of the first switching elements in each first switching element group SG1 is not limited to that shown in FIG. 6, and may be other quantity, such as 2, 4, 5, or more.

In this embodiment, each bonding pad 18 may be electrically connected to a corresponding probe pad 20 in a one-to-one correspondence, so that the number of the probe pads 20 may be equal to the number of the bonding pads 18, but not limited thereto. In some embodiments, the number of the probe pads 20 may differ from the number of the bonding pads 18. Other parts and the manufacturing method of the electronic device 4 in this embodiment may be similar or identical to those of the electronic device 1 and its manufacturing method mentioned above and shown in FIGS. 1A to 1C, and therefore reference may be made to the above-mentioned description and will not be repeated here.

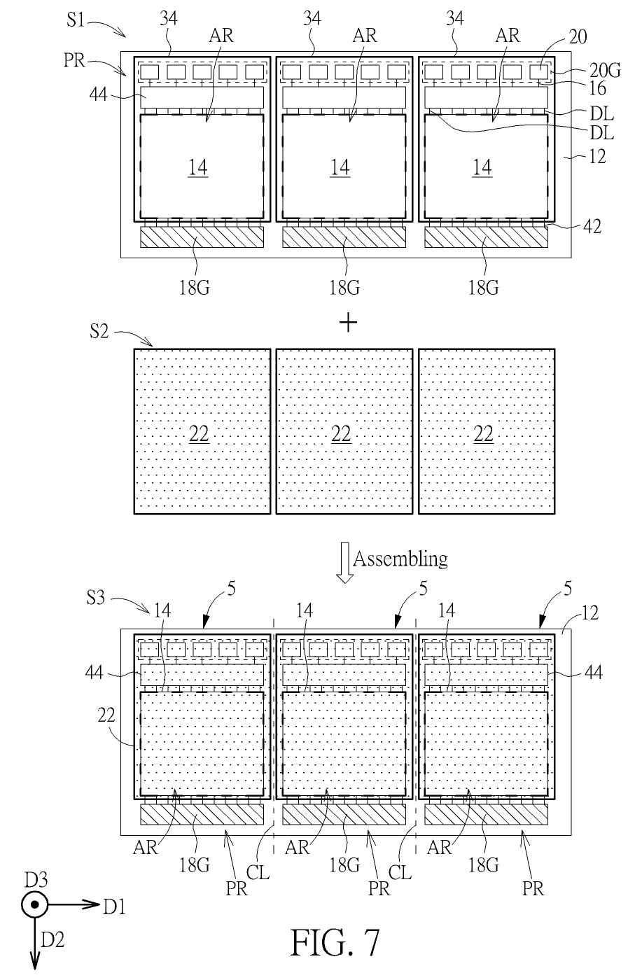

Refer to FIG. 7, which schematically illustrates a top view of an electronic device during an assembling process according to a fourth embodiment of the present disclosure. As shown in FIG. 7, a difference between the electronic device 5 provided in this embodiment and the electronic device 4 of FIG. 5 is that the probe pads 20 and the bonding pads (e.g., the bonding pad 18 shown in FIG. 1B or FIG. 6) are located on two opposite sides of the active region AR. Additionally, the first multiplexer 44 may be located between the probe pads 20 and the active region AR. Since the connection relationship among the probe pads 20, the first multiplexer 44, and the wires DL may be the same as that in the embodiment of FIG. 6, reference may be made to the above-mentioned contents and no further details will be described here. In this embodiment, the probe pads 20, the wires 16, and the first multiplexer 44 may be located in the cavity (e.g., the cavity 24 shown in FIG. 1B).

As shown in FIG. 7, the electronic device 5 may further include a plurality of wires 42 disposed between the active region AR and the bonding pad group 18G, in which the wires 42 electrically connect the bonding pads 18 of the bonding pad group 18G to the corresponding electronic units (e.g., the electronic units 14U shown in FIG. 2). In this embodiment, each bonding pad of the bonding pad group 18G may be electrically connected to the corresponding wire DL through the wire 42 and electronic element 14, and further to the corresponding probe pad 20, but not limited thereto. In some embodiments, the protective layer 26 as shown in FIG. 1B may be disposed on the wires 42. For example, the protective layer 26 of FIG. 1B may be simultaneously disposed on the wires 42, or the protective layer 26 of FIG. 1C may further include a plurality of protective wires respectively disposed on the wires 42. Other parts and the manufacturing method of the electronic device 5 in this embodiment may be similar or identical to those of the electronic device 4 and its manufacturing method in FIG. 5, and therefore reference may be made to the above-mentioned description and will not be repeated here.

Refer to FIGS. 8 and 9. FIG. 8 schematically illustrates a top view of an electronic device during an assembling process according to a fifth embodiment of the present disclosure, and FIG. 9 schematically illustrates an enlarged view of a first multiplexer, the probe pads, a second multiplexer, and the bonding pads according to the fifth embodiment of the present disclosure. As shown in FIGS. 8 and 9, a difference between the electronic device 6 provided in this embodiment and electronic device 4 of FIG. 5 is that the electronic device 6 further includes a second multiplexer 46 disposed on the substrate 12 and located in the cavity (e.g., the cavity 24 shown in FIG. 1B), wherein the first multiplexer 44 and second multiplexer 46 both are located on the same side of the active region AR. In this embodiment, the second multiplexer 46 is located between the bonding pad group 18G (e.g., the bonding pad 18 shown in FIG. 1B) and the probe pads 20; in other words, it may be located between the bonding pads and the first multiplexer 44.

Specifically, the second multiplexer 46 may include a plurality of second switching element groups SG2 for switching the electrical connection path between the bonding pads 18 and the probe pads 20 (or the wires 16). For example, each second switching element group SG2 may include a second switching element SW4 and a second switching element SW5. The electronic device 6 may further include a plurality of wires 48, wherein the first ends of the second switching element SW4 and the second switching element SW5 in one of the second switching element groups SG2 are electrically connected to each other and to the same bonding pad 18 through a corresponding wire 48, and the second ends of the second switching element SW4 and the second switching element SW5 in this second switching element group SG2 are electrically connected to different probe pads 20, respectively. For example, a bonding pad 18a may be electrically connected to the probe pad 20a and the probe pad 20b through the corresponding second switching element group SG2, and a bonding pad 18b may be electrically connected to the probe pad 20c and the probe pad 20d through corresponding second switching element group SG2. Additionally, the control ends of the second switching elements SW4 may be electrically connected to the same control signal terminal E4, and the control ends of the second switching elements SW5 may be electrically connected to the same control signal terminal E5. By adjusting switching signals provided to the control signal terminal E4 and the control signal terminal E5, the second switching elements SW4 and the second switching elements SW5 may be turned on at different times, such that each bonding pad 18 is able to be electrically connected to different probe pads 20 (or wires 16) at different times, but not limited thereto. In other words, the number of the bonding pads 18 in this embodiment may be less than the number of the probe pads 20, which may help reduce the number of the bonding pads 18 or increase the areas of the bonding pads 18. The second switching element (e.g., the second switching element SW4, and the second switching element SW5) may include a transistor or other suitable switching elements. The second multiplexer 46 may, for example, be formed during the step of forming the electronic element 14. In some embodiments, the number of the second switching elements in each second switching element group SG2 is not limited to that shown in FIG. 9, and may be other numbers, such as three or more. In some embodiments, a protective layer 26 as shown in FIG. 1B may be disposed on the wires 48. For example, the protective layer 26 of FIG. 1B may be simultaneously disposed on the wires 48 and the wires 16, or the protective layer 26 of FIG. 1C may further include a plurality of protective wires respectively disposed on the wires 48.

In this embodiment, since the first multiplexer 44 may be similar or identical to the embodiment shown in FIG. 6, reference may be made to the above-mentioned contents, and no further details will be described here. With the installation of the first multiplexer 44, the number of the probe pads 20 may be less than the number of the wires DL. Furthermore, by utilizing both the first multiplexer 44 and the second multiplexer 46, the number of the bonding pads 18 may also be less than the number of the wires DL. Other parts and the manufacturing method of the electronic device 6 in this embodiment may be similar or identical to those of the electronic device 4 and its manufacturing method in FIG. 5, and therefore reference may be made to the above-mentioned description and will not be repeated here.

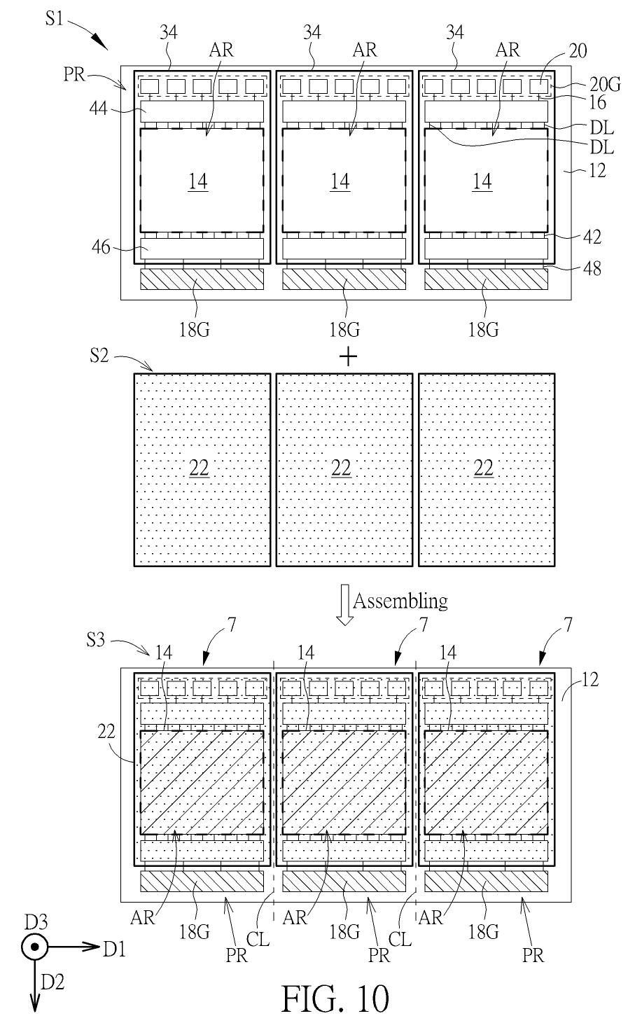

Refer to FIG. 10, which schematically illustrates a top view of an electronic device during an assembling process according to a sixth embodiment of the present disclosure. As shown in FIG. 10, a difference between the electronic device 7 provided in this embodiment and the electronic device 6 of FIG. 8 is that the first multiplexer 44 and the second multiplexer 46 are located on two opposite sides of the active region AR. In other words, the probe pads 20 and the bonding pad group 18G (including, for example, multiple bonding pads 18 as shown in FIG. 1B or FIG. 9) are located on two opposite sides of the active region AR. Furthermore, the first multiplexer 44 may be located between the probe pads 20 and the active region AR, and the second multiplexer 46 may be located between the bonding pads and the active region AR. The probe pads 20 may be electrically connected to the corresponding electronic units in electronic element 14 through the first multiplexer 44, and the bonding pads may be electrically connected to the corresponding electronic units (e.g., the electronic units 14U shown in FIG. 2) of electronic element 14 through the second multiplexer 46, such that the bonding pads may be electrically connected to the wires 16, including both the first wire and second wire, through the second multiplexer 46 and further to the corresponding probe pads 20. In this embodiment, the first wire and second wire may be, for example, two data lines, respectively. The first multiplexer 44 and second multiplexer 46 in this embodiment may be similar or identical to those in the embodiment of FIG. 9, and the electrical connection relationships among the probe pads 20, the wires 16, the first multiplexer 44, and the wires DL may be similar or identical to those in the embodiment of FIG. 7, so that reference may be made to the above-mentioned contents and will not be repeated here. In this embodiment, the probe pads 20, the wires 16, the first multiplexer 44, and the second multiplexer 46 may be located in the cavity (e.g., cavity 24 shown in FIG. 1B).

As shown in FIG. 10, the electronic device 7 may further include a plurality of wires 42 and a plurality of wires 48, wherein the wires 42 are disposed between the second multiplexer 46 and the active region AR, for electrically connecting the second multiplexer 46 to the electronic element 14, and the wires 48 are disposed between the bonding pad group 18G and the second multiplexer 46, for electrically connecting the bonding pads of the bonding pad group 18G to the second multiplexer 46. In this embodiment, the number of the wires 42 may be, for example, the same as the number of the wires DL, but not limited thereto. In FIG. 10, the number of the wires 48 may differ from the number of the wires 16, for example, being less than the number of the wires 16. In other words, the number of the bonding pads may be less than the number of the probe pads 20, but not limited thereto. In some embodiments, the numbers of the bonding pads and the probe pads 20 may be adjusted according to the number of the first switching elements of the first multiplexer 44 and the number of the second switching elements of the second multiplexer 46. The number of the bonding pads and the probe pads 20 may alternatively be the same. Other parts and the manufacturing method of the electronic device 7 in this embodiment may be similar or identical to those of the electronic device 6 and its manufacturing method in FIG. 8 and FIG. 9, and therefore reference may be made to the above-mentioned description and will not be repeated here.

In summary, in the electronic device and its manufacturing method of the present disclosure, since the bonding pads and the probe pads are separately disposed, damage to the bonding pads during testing through the probe pads and/or subsequent process steps may be prevented or reduced, thereby improving the reliability of bonding between the bonding pads and the external elements.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate comprising an active region and a peripheral region;
a plurality of electronic units disposed in the active region;
a first wire disposed on the substrate and electrically connected to one of the plurality of electronic units;
a bonding pad disposed in the peripheral region and electrically connected to the first wire;
a probe pad disposed in the peripheral region and electrically connected to the first wire; and
a cover plate disposed opposite to the substrate, wherein the cover plate is bonded to the substrate to form a cavity;
wherein the electronic units and the probe pad are disposed in the cavity, and the bonding pad is disposed outside the cavity.

2. The electronic device according to claim 1, wherein the bonding pad and the probe pad are located on a same side of the active region.

3. The electronic device according to claim 1, wherein the bonding pad and the probe pad are located on two opposite sides of the active region, respectively.

4. The electronic device according to claim 1, further comprising a branch wire electrically between the first wire and the probe pad.

5. The electronic device according to claim 1, further comprising a second wire disposed on the substrate and electrically connected to at least another of the plurality of electronic units.

6. The electronic device according to claim 1, further comprising a protective layer disposed on the first wire, wherein the protective layer comprises a first opening and a second opening, and the probe pad and the bonding pad are electrically connected to the first wire through the first opening and the second opening, respectively.

7. The electronic device according to claim 1, further comprising a protective wire disposed on the first wire, and the protective wire comprises a conductive material.

8. The electronic device according to claim 1, wherein the first wire is a data line or a scan line.

9. The electronic device according to claim 1, further comprising a third wire electrically connected to the one of the plurality of electronic units, wherein the first wire and the third wire extend along different directions.
